(19) United States
(12) Patent Application Publication
(10) Pub. No.: US 2004/0222522 A1
(43) Pub. Date: Nov. 11, 2004

(54) Semiconductor device and manufacturing method of the same

(76) Inventor: Soichi Homma, Kawasaki-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/798,433

(22) Filed: Mar. 12, 2004

(30) Foreign Application Priority Data
Mar. 13, 2003 (JP) 2003-067607

(51) Int. Cl. H01L 21/48; H01L 23/52

(52) U.S. Cl. 257/737; 438/613; 257/778; 438/108

(57) ABSTRACT

A semiconductor device includes a semiconductor chip having a semiconductor element or an integrated circuit formed in the semiconductor chip, a low dielectric constant insulating film formed on a surface of the semiconductor chip, and a plurality of bump electrodes being provided on the surface of the semiconductor chip, a wiring board having a plurality of connecting electrodes being electrically connected to the bump electrodes, and a resin molding filled in a space between the semiconductor chip and the wiring board, the electrically connected bump electrodes and the connecting electrodes being arranged in the space, wherein the resin molding is formed of a resin having a flux function and changed from liquid to solid when the bump electrodes are in a molten state.

### CROSS-REFERENCE TO RELATED APPLICATIONS

This application is based upon and claims the benefit of priority from prior Japanese Patent Application No. 2003-067607, filed Mar. 13, 2003, the entire contents of which are incorporated herein by reference.

### BACKGROUND OF THE INVENTION

1. Field of the Invention

This invention relates to a semiconductor device in which a semiconductor chip is connected, with bump electrodes thereof, onto a wiring board by flip chip method.

2. Description of the Related Art

A flip chip semiconductor device comprises a wiring board, such as a printed board, having an external connecting terminal, a semiconductor chip connected onto the wiring board by flip chip method, and a resin molding filled between the semiconductor chip and the wiring board. FIG. 28 is a schematic cross-sectional view of a conventional flip chip semiconductor device. A semiconductor chip 100 in which a semiconductor element or an integrated circuit is formed is obtained by dicing a semiconductor wafer of silicon or the like. Insulating films such as a silicon oxide film (SiO₂) and a silicon nitride film (SiN) are used for insulation between layers of the semiconductor element and integrated circuit. As semiconductor devices are more microminiaturized, a high relative dielectric constant of the insulating films causes problems such as signal delay. Therefore, in current semiconductor devices, a low dielectric constant insulating film 104 having a low relative dielectric constant (having a relative dielectric constant of about 3.5 or less), which is generally called Low K film, is used in at least a part of the semiconductor device. A protective insulating film (passivation film) 105 such as SiO₂/SiN is formed on the low dielectric constant insulating film 104. Bump electrodes 103 serving as external terminals are formed on the passivation film 105. Connecting electrodes (connecting pads, not shown) are formed on a surface of the semiconductor chip 100, and the bump electrodes 103 are formed on the respective connecting electrodes and electrically connected to the respective connecting electrodes, and electrically connected to the semiconductor element or the integrated circuit in the semiconductor chip 100 via the connecting electrodes.

In the meantime, wire, not shown, and connecting electrodes (connecting pads) 106 electrically connected to the wire are formed on a surface, on which the semiconductor chip 100 is mounted, of a wiring board 101 such as a printed wiring board supporting the semiconductor chip 100. The bump electrodes 103 are connected to the respective connecting pads 106. Bump electrodes 102 are provided on the other surface (back surface) of the wiring board 101, with respective connecting pads interposed therebetween, not shown. The bump electrodes 102 are used as external connecting terminals of the semiconductor device. A resin molding 110 formed of thermosetting epoxy resin or the like is filled in a space between the semiconductor chip 100 and the wiring board 101, in which the bump electrodes 103 are arranged.

In a process of forming the semiconductor device, a resin having a flux function is applied to the wiring board 101, and then the bump electrodes 103 are arranged on the respective connecting pads 106 and pressed thereon. Thereafter, heat is applied to connect the bump electrodes 103 and the connecting pads 106 and form the resin molding 110. A reflow furnace is used for this heating. A reflow furnace is also used when the bump electrodes 102 are attached to the wiring board 101.

As prior art of flip chip connecting, disclosed is a technique of flip chip connecting between metal electrodes (bump electrodes) of a semiconductor chip and solder terminals (connecting pads) of a wiring board with thermosetting resin, in which the metal electrodes and the solder terminals are connected and solidified, and thereafter the thermosetting resin is set to enhance reliability of connection (Jpn. Pat. Appln. KOKAI Pub. No. 11-233558 (FIG. 1, columns 4-5)). There is also a technique of avoiding faulty connection, in which solder bumps are formed on a semiconductor chip or a wiring board, the chip and the wiring board are arranged opposite to each other with thermosetting resin interposed therebetween, the chip and the wiring board are connected by heating and melting the bumps, and thereafter the resin is set (Jpn. Pat. Appln. KOKAI Pub. No. 2001-351945 (FIG. 1, Page 3)). There is also a technique in which resin having a flux function is applied onto a circuit board surface, a semiconductor chip and the circuit board are positioned, flip chip connecting is performed by melting bumps, and thereafter the resin is set at a higher temperature (Jpn. Pat. Appln. KOKAI Pub. No. 2002-261118).

As described above, heating is performed in a reflow furnace or the like, when bump electrodes are attached and when the semiconductor chip is attached to the wiring board. In the heating, the semiconductor chip and the wiring board are expanded by heat. However, the thermal expansion coefficient a of semiconductor chips is 3-4 ppm, while the thermal expansion coefficient α of wiring boards is 10-17 ppm. Since the difference in the coefficient between them is considerably large, stress is applied to the resin molding in heating. This does not cause a large problem in past semiconductor devices which use a high adhesion film, such as a silicon oxide film and a silicon nitride film, as an insulation film. However, the stress causes a large problem in current semiconductor devices using low dielectric constant insulating films which are sensitive to stress. As low dielectric constant insulating films, there may be used insulating films formed of a material of a high relative dielectric constant. The dielectric constant thereof has been lowered by forming the film at low density. Such low dielectric constant films are fragile since they are formed at low density.

Specifically, there are following problems in flip chip (FC) connecting of a semiconductor chip to a wiring board.

First, if a film called Low K film formed of a low dielectric constant material (low dielectric constant insulating film) is used in a semiconductor chip, Low K film is broken or peels off under bump electrodes in flip chip connecting, due to low strength of the Low K film.

The above problem can be solved by setting the thermal expansion coefficient of the wiring board close to that of the semiconductor chip. However, this solution enhances the possibility of fatigue failure of its BGA (Ball Grid Array) portion in reliability test.

Further, if flip chip connecting is performed by using flux, the bump portions are at risk of peeling off by inappropriate impact directly after reflow.

### BRIEF SUMMARY OF THE INVENTION

According to an aspect of the present invention, there is provided a semiconductor device comprising a semiconductor chip having a semiconductor element or an integrated circuit formed in the semiconductor chip, a low dielectric constant insulating film formed on a surface of the semiconductor chip, and a plurality of bump electrodes being provided on the surface of the semiconductor chip; a wiring board having a plurality of connecting electrodes being electrically connected to the bump electrodes; and a resin molding filled in a space between the semiconductor chip and the wiring board, the electrically connected bump electrodes and the connecting electrodes being arranged in the space, wherein the resin molding is formed of a resin having a flux function and changed from liquid to solid when the bump electrodes are in a molten state.

According to another aspect of the present invention, there is provided a method of manufacturing a semiconductor device, comprising:

forming a plurality of bump electrodes on a surface of a semiconductor chip, in which a semiconductor element or an integrated circuit is formed, with a low dielectric constant insulating film formed on the surface of the semiconductor chip;

interposing a resin, which has a flux function between the semiconductor chip and a wiring board in which a plurality of connecting electrodes are formed;

aligning the bump electrodes and the respective connecting electrodes with the resin interposed therebetween, and pressing the semiconductor chip and the connecting electrodes against each other; and

heating the semiconductor chip and the wiring board to electrically connect the bump electrodes to the respective connecting electrodes, and to form a resin molding formed of the resin to fill a space between the semiconductor chip and the wiring board,

wherein the resin is a resin which changes from liquid to solid when the bump electrodes are in a molten state in connecting of the bump electrodes to the respective connecting electrodes.

According to a further aspect of the present invention, there is provided a method of manufacturing a semiconductor device, comprising:

forming a plurality of bump electrodes on a surface of a semiconductor chip, in which a semiconductor element or an integrated circuit is formed, with a low dielectric constant insulating film formed on the surface of the semiconductor chip;

interposing a first resin, which has a flux function, in the vicinity of the semiconductor chip, between the semiconductor chip and a wiring board in which a plurality of connecting electrodes are formed;

interposing a second resin, which has a flux functions and contains no filler, in the vicinity of the wiring board, between the semiconductor chip and the wiring board in which the plurality of connecting electrodes are formed;

aligning the bump electrodes and the respective connecting electrodes with the first and second resins interposed therebetween, and pressing the semiconductor chip and the connecting electrodes against each other; and

heating the semiconductor chip and the wiring board to electrically connect the bump electrodes to the respective connecting electrodes, and to form a resin molding formed of the first and second resins to fill a space between the semiconductor chip and the wiring board,

wherein the first and second resins are resins which change from liquid to solid when the bump electrodes are in a molten state in connecting of the bump electrodes to the respective connecting electrodes.

According to a further aspect of the present invention, there is provided a method of manufacturing a semiconductor device, comprising:

forming a plurality of bump electrodes on a surface of a semiconductor chip, in which a semiconductor element or an integrated circuit is formed, with a low dielectric constant insulating film formed on the surface of the semiconductor chip;

interposing a first resin, which has a flux function, in the vicinity of the semiconductor chip, between the semiconductor chip and a wiring board in which a plurality of connecting electrodes are formed;

interposing a second resin, which has a flux functions, in the vicinity of the wiring board, between the semiconductor chip and the wiring board in which the plurality of connecting electrodes are formed;

interposing a third resin, which has a flux function and contains no filler, between the first resin and the second resin;

aligning the bump electrodes and the respective connecting electrodes with the first, second and third resins interposed therebetween, and pressing the semiconductor chip and the connecting electrodes against each other; and

heating the semiconductor chip and the wiring board to electrically connect the bump electrodes to the respective connecting electrodes, and to form a resin molding formed of the first, second and third resins to fill a space between the semiconductor chip and the wiring board,

wherein the first, second and third resins are resins which change from liquid to solid when the bump electrodes are in a molten state in connecting of the bump electrodes to the respective connecting electrodes.

### BRIEF DESCRIPTION OF THE SEVERAL VIEWS OF THE DRAWING

FIG. 1 is a cross-sectional view of a device structure in a manufacturing step of a semiconductor device according to a first embodiment of the present invention.

FIG. 2 is a cross-sectional view of a device structure in a manufacturing step, following the step shown in FIG. 1, of the semiconductor device according to the first embodiment of the present invention.

FIG. 3 is a cross-sectional view of a device structure in a manufacturing step, following the step shown in FIG. 2, of the semiconductor device according to the first embodiment of the present invention.

FIG. 4 is a cross-sectional view of a device structure in a manufacturing step, following the step shown in FIG. 3, of the semiconductor device according to the first embodiment of the present invention.

FIG. 5 is a cross-sectional view of a device structure in a manufacturing step, following the step shown in FIG. 4, of the semiconductor device according to the first embodiment of the present invention.

FIG. 6 is a cross-sectional view of a device structure in a manufacturing step, following the step shown in FIG. 5, of the semiconductor device according to the first embodiment of the present invention.

FIG. 7 is a cross-sectional view of a device structure in a manufacturing step, following the step shown in FIG. 6, of the semiconductor device according to the first embodiment of the present invention.

FIG. 8 is a cross-sectional view of a device structure in a manufacturing step, following the step shown in FIG. 7, of the semiconductor device according to the first embodiment of the present invention.

FIG. 9 is a reflow profile for explaining reflow conditions in flip chip connecting according to the first embodiment of the present invention.

FIG. 10 is a diagram showing an SAT image for explaining a connecting state of a semiconductor chip and a wiring board.

FIG. 11 is a diagram showing an SAT image for explaining a connecting state of a semiconductor chip and a wiring board.

FIG. 12 is a diagram showing an IR image for explaining a connecting state of a semiconductor chip and a wiring board.

FIG. 13 is a diagram showing an IR image for explaining a connecting state of a semiconductor chip and a wiring board.

FIG. 14 is a characteristic diagram showing a relationship between a coefficient of elasticity of a resin forming a resin molding and the reflow profile.

FIG. 15 is a cross-sectional view illustrating an attachment structure of a bump electrode attached to a semiconductor chip.

FIG. 16 is a cross-sectional view illustrating another attachment structure of a bump electrode attached to a semiconductor chip.

FIG. 17 is a cross-sectional view illustrating another attachment structure of a bump electrode attached to a semiconductor chip.

FIG. 18 is a cross-sectional view of a device structure in a manufacturing step of a semiconductor device according to a second embodiment of the present invention.

FIG. 19 is a cross-sectional view of a device structure in a manufacturing step, following the step shown in FIG. 18, of the semiconductor device according to the second embodiment of the present invention.

FIG. 20 is a cross-sectional view of a device structure in a manufacturing step of a semiconductor device according to a third embodiment of the present invention.

FIG. 21 is a cross-sectional view of a device structure in a manufacturing step, following the step shown in FIG. 20, of the semiconductor device according to the third embodiment of the present invention.

FIG. 22 is a cross-sectional view of a device structure in a manufacturing step, following the step shown in FIG. 21, of the semiconductor device according to the third embodiment of the present invention.

FIG. 23 is a cross-sectional view of a device structure in a manufacturing step, following the step shown in FIG. 22, of the semiconductor device according to the third embodiment of the present invention.

FIG. 24 is a cross-sectional view of a device structure in a manufacturing step of a semiconductor device according to a fourth embodiment of the present invention.

FIG. 25 is a cross-sectional view of a device structure in a manufacturing step, following the step shown in FIG. 24, of the semiconductor device according to the fourth embodiment of the present invention.

FIG. 26 is a cross-sectional view of a device structure in a manufacturing step, following the step shown in FIG. 25, of the semiconductor device according to the fourth embodiment of the present invention.

FIG. 27 is a cross-sectional view of an attachment structure of the bump electrode attached to the semiconductor chip according to the first embodiment of the present invention.

FIG. 28 is a cross-sectional view of a conventional flip chip semiconductor device.

### DETAILED DESCRIPTION OF THE INVENTION

Embodiments of the present invention are explained with reference to drawings.

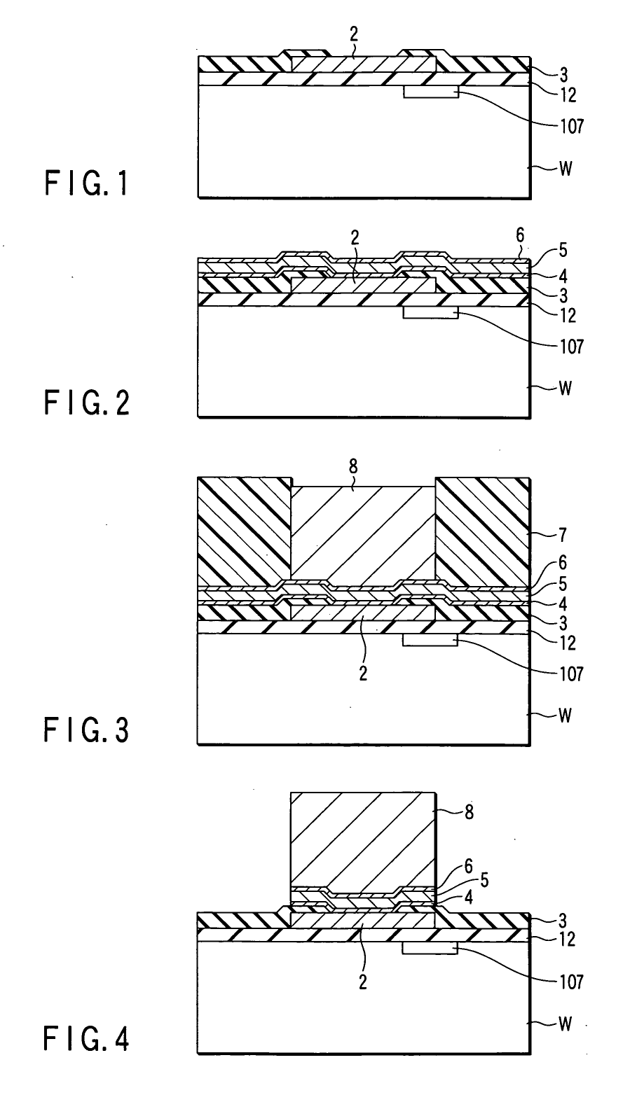

First, a first embodiment of the present invention is explained with reference to FIGS. 1-17 and 27.

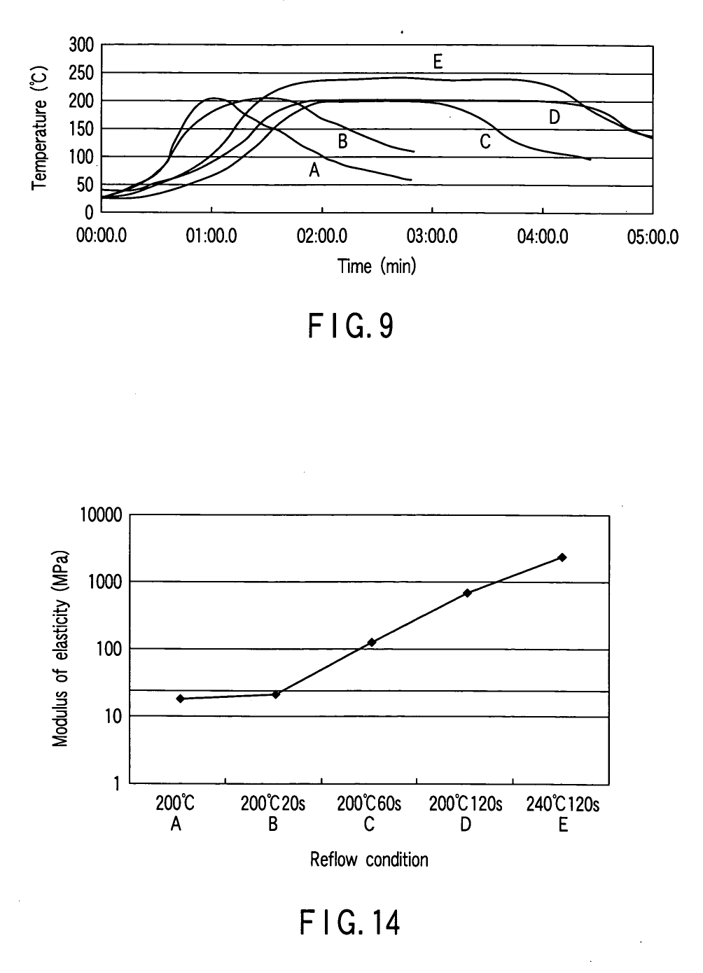

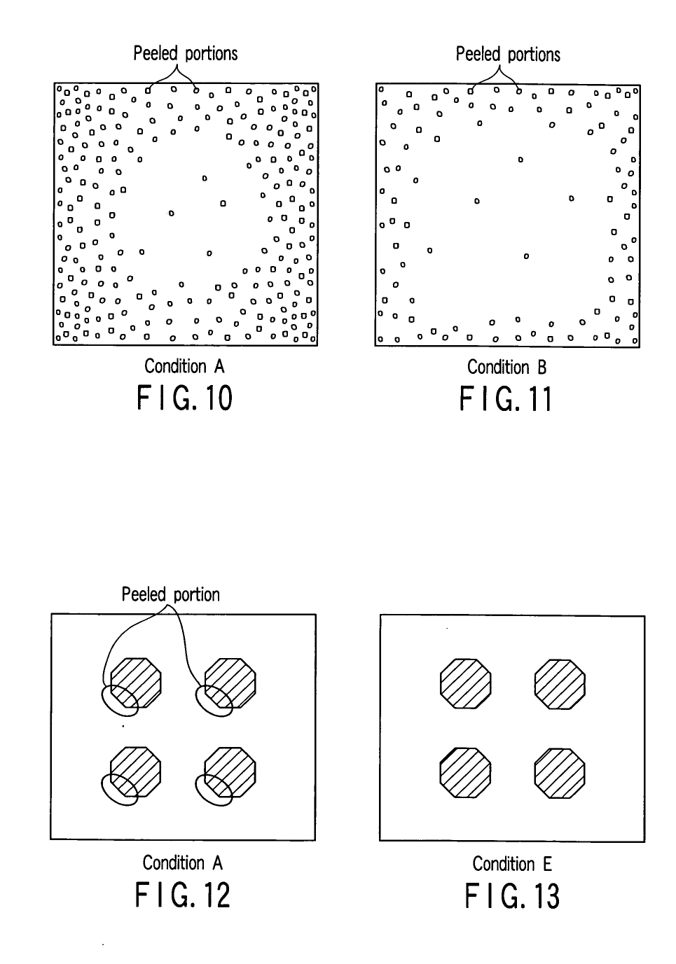

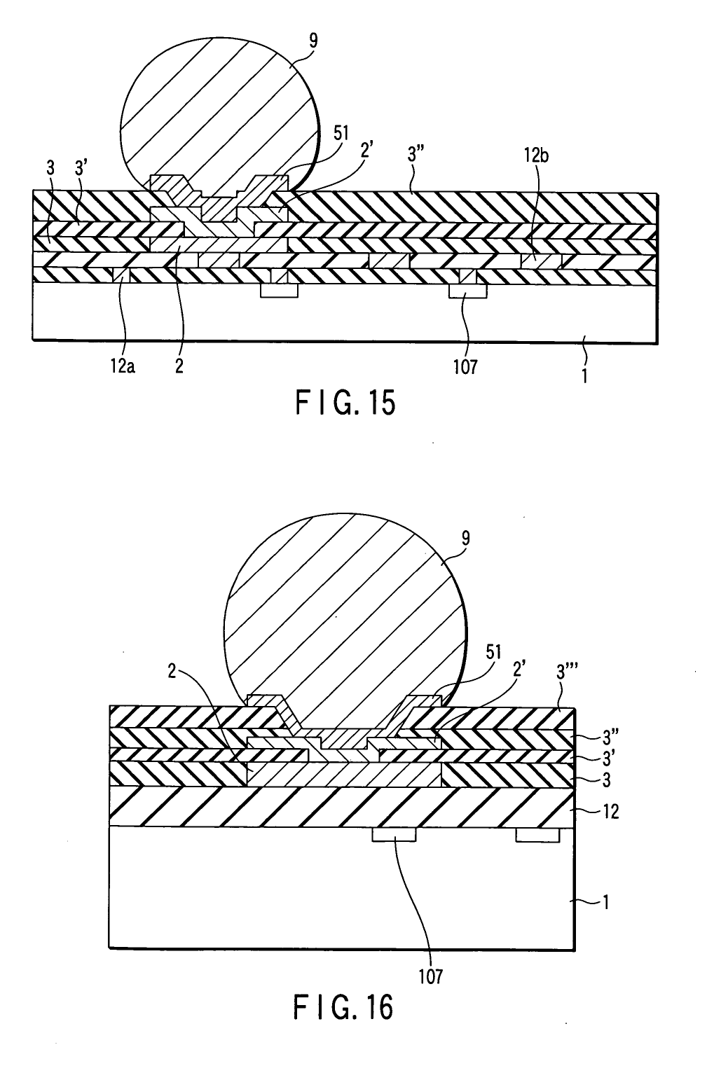

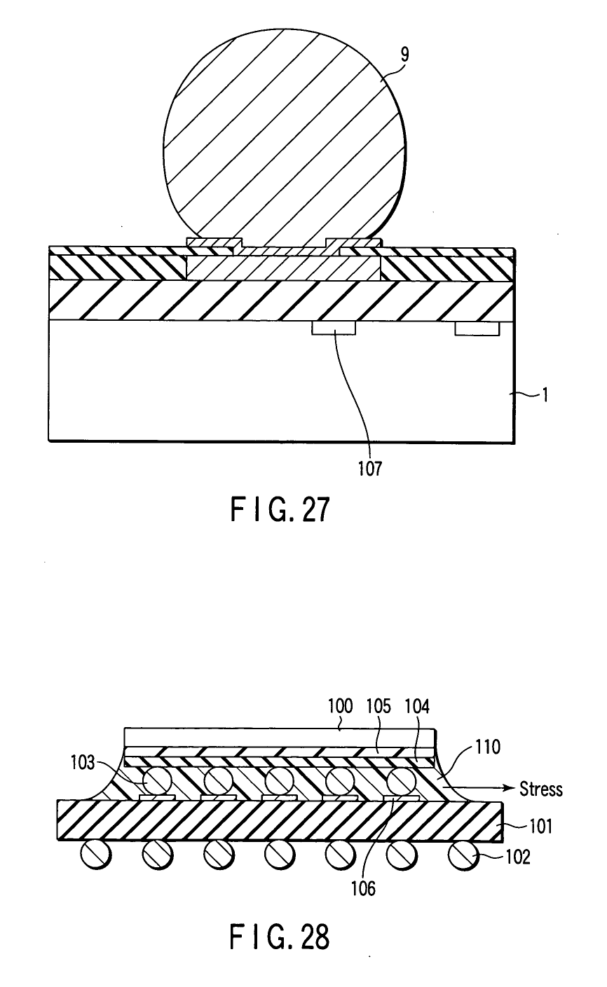

FIGS. 1 to 8 are cross-sectional views for explaining a process from a step of connecting bump electrodes to a semiconductor chip to a step of flip chip connecting the semiconductor chip to a wiring board, FIG. 9 is a reflow profile for explaining reflow conditions in flip chip connecting, FIGS. 10 and 11 are diagrams illustrating SAT images for explaining connection between the semiconductor chip and the wiring board, FIGS. 12 and 13 are diagrams illustrating an IR image for illustrating connection between the semiconductor chip and the wiring board, FIG. 14 is a characteristic diagram illustrating a relationship between a coefficient of elasticity of resin forming a resin molding and the reflow profile, FIG. 27 is a cross-sectional view of the semiconductor chip, which illustrates an attachment structure of a bump electrode attached to the semiconductor chip, and FIGS. 15 to 17 are cross-sectional views of the semiconductor chip, illustrating other attachment structures of the bump electrode attached to the semiconductor chip.

FIGS. 1 to 8 illustrate a method of manufacturing a semiconductor device according to the first embodiment. A semiconductor wafer W formed of silicon or the like is prepared. The semiconductor wafer W has a diameter of 8 inches and a thickness of 725 μm, and has a wire (not shown) containing Cu. The semiconductor wafer W is divided into semiconductor chip regions. Semiconductor elements or integrated circuits 107 are formed in each of the semiconductor chip regions (FIG. 1). A low dielectric constant insulating film 12 called Low K film is formed in each of the chip regions. For example, an SiOC film is used as the Low K film. Next, a Cu pad 2 is formed on the low dielectric constant insulating film (SiOC film) 12 on the semiconductor wafer. The Cu pad 2 is electrically connected to the semiconductor elements or integrated circuits 107 via the wire (not shown) containing Cu. A surface of the semiconductor wafer W is coated with a passivation film 3 formed of SiO₂/SiN or the like, with the Cu pad 2 partially exposed (FIG. 1). Next, a titanium film 4, a nickel film 5, and a palladium film 6 are successively formed over surface of the semiconductor wafer W by using a sputtering device and an electron beam deposition device or the like, to form a barrier metal layer formed of these films (FIG. 2). Next, a photoresist 7 with a film thickness of about 50 μm is coated on the barrier metal layer. Then, an opening of a 100 μm square is formed in the photoresist 7. The opening overlaps with the Cu pad 2. A low-melting metal 8 or the like for a bump electrode is formed by plating, with a thickness of 50 μm, in the opening.

For example, in the case of forming Sn/Pb eutectic solder, the semiconductor wafer W on which the resist pattern has been formed is soaked in a solution containing 30 g/l of tin, 20 g/l of lead, 100 g/l of alkanesulfonic acid, and an additive mainly consisting of a surface active agent. Then, plating is performed while the solution is slowly stirred at the bath temperature of 20° C., with the barrier metal layer used as cathode and the Sn/Pb plate used as anode, under the condition of a current density of 1 A/dm² (FIG. 3).

Thereafter, the photoresist 7 is removed by using acetone or a known peeling solution, and the Pd, Ni, and Ti films 6, 5 and 4 being the exposed barrier metal layer are etched. The paradium film 6 and the nickel film 5 are etched by using an aqua regia etching solution. An etching solution of ethylenediaminetetraacetic acid can be used for etching the titanium film 4 (FIG. 4). Lastly, a flux is applied to the semiconductor wafer W. The wafer W is heated in a nitrogen atmosphere at 220° C. for 30 seconds to reflow the solder metal and form a solder bump (bump electrode) 9 (FIG. 5). The solder bump electrodes 9 is formed on the Cu pad 2 and electrically connected to the Cu pad 2, and also electrically connected to the semiconductor element or the integrated circuit 107 in the semiconductor chip via the Cu pad 2. Thereafter, the semiconductor wafer W, on which the solder bump 9 has been formed, is subjected to an electrical test, and diced to form plural semiconductor chips 1 (FIG. 6). The semiconductor chip is subjected to flip chip connecting. The surface of the semiconductor chip 1 is protected by coating of the passivation film 3 formed of SiO₂/SiN.

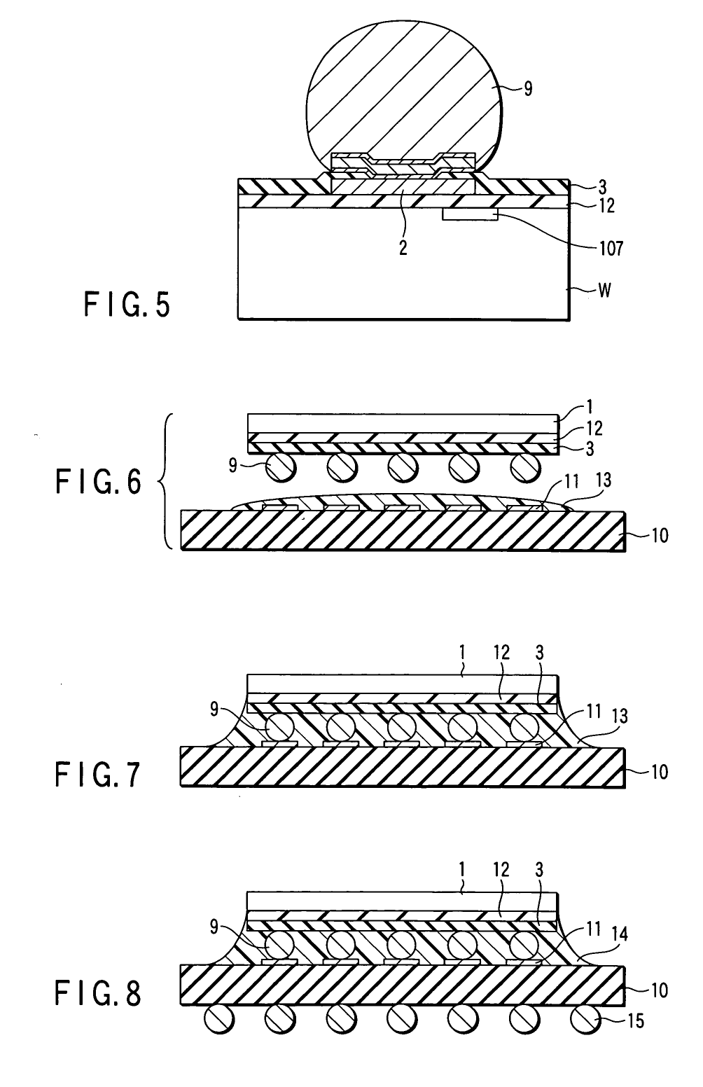

Next, an oxide film formed on the surface of the solder is removed, and a resin 13 having a flux function is applied with a proper amount onto connecting pads 11 of a wiring board 10. The connecting pads 11 on the wiring board 10 such as a substrate are aligned with the respective solder bumps 9, and they are provisionally fixed by pressing (FIG. 6). Thereafter, the semiconductor chip 1 and the wiring board 10 are carried to a reflow furnace, and the solder bumps 9 and the respective connecting pads 11 are connected therein (FIG. 7). In the connecting, a condition is set that the resin 13 is changed from liquid to solid when the solder is in a molten state. The coefficient of elasticity of the resin is 20 MPa, preferably 100 MPa or more. The resin having the flux function forms a resin molding 14 between the semiconductor chip 1 and the wiring board 10. FIG. 9 shows a reflow profile based on various conditions, and FIGS. 10 and 11 illustrate results of comparison between the reflow conditions with respect to Low K film peeling. Reflow was performed under the various conditions of the peak of 200° C. (condition A), 200° C. and 20 seconds (condition B), 200° C. and 60 seconds (condition C), 200° C. and 120 seconds (condition D), and 240° C. and 120 seconds (condition E), and it was checked whether the Low K film peeled off. As shown in the SAT images of FIGS. 10 and 11, the Low K film is peeled by reflow at the peak of 200° C. (condition A) and at 200° C. for 20 seconds (condition B). Further, as shown in FIG. 12, peeling was found at the peak of 200° C. (condition A) in the portions under the pads of the same samples through an IR microscope.

In comparison with this, no peeling occurred in reflow performed at 200° C. for 60 seconds (condition C), at 200° C. for 120 seconds (condition D), and at 240° C. for 120 seconds (condition E). Also, no peeling occurred in reflow performed at 240° C. for 120 seconds (condition E) (FIG. 13). As described above, the resin state can be changed by changing the reflow peak time. The states of the resin under the above conditions C, D and E were found to be the states in which the resin changed from liquid to solid when the bump electrode was in a molten state. The coefficient of elasticity of the resin in these states was 20 MPa or more, as a result of calculation based on the curve of the board. It proved that no peeling occurs with such a coefficient of elasticity of the resin (FIG. 14). Although the chip samples after reflow were further cured at 150° C. for 2 hours as after-cure, no peeling of the Low K films occurred.

A semiconductor device was manufactured according to the above process, and reliability of the device was checked by a temperature cycle test. A 15 mm square chip in which 2500 bumps are formed was used as semiconductor chip, and a sample was made by mounting the chip on a resin board serving as a wiring board. The temperature cycle test was performed with a cycle comprising −55° C. (30 min), 25° C. (5 min) and 125° C. (30 min) performed in this order.

As a result, no break was found in the connecting portions after 1500 cycles. Further, no peeling of the Low K film 12 formed in the semiconductor element was occurred. Furthermore, neither the Low K film 12 nor bumps peeled off after moisture absorption reflow evaluation.

In the semiconductor device formed by flip chip connecting of the semiconductor chip 1 to the wiring board 10, external connecting terminals are further attached to the wiring board 10. In this embodiment, bump electrodes 15 such as solder bumps are attached to the back surface of the wiring board 10. A method of attaching the bump electrodes 15 is the same as the method of attaching the solder bumps 9 to the semiconductor chip 1. The bump electrodes 15 are electrically connected to the wire, not shown, of the wiring board 10 (FIG. 8).

Although this embodiment shows an example of using an SiOC film as Low K film, the Low K film may be formed of one of HSQ (Hydrogen Silsesquioxane), Organic Silica, porous HSQ, and BCB (Benzocyclobutene), or a laminated film or porous film thereof. An SiO₂ film, an SiN film or a film obtained by superposing these films may be used as the Low K film.

The resin having the flux function may be a resin in which a flux is mixed, a resin including a curing agent having a flux effect, and a resin using an acid anhydride as such a curing agent, for example. Further, a resin in which filler is mixed may be used. As the resin material, used are epoxy-based resin, acryl-based resin, silicon-based resin, and polyimidebased resin, etc. Further, although the Sn—Pb solder is used as the metal bumps in this embodiment, the metal bumps may be formed of Au, Ag, Cu, Ni, Fe, Pd, Sn, Pb, Bi, Zn, In, Sb, or Ge, or a mixture or compound thereof. The connecting pads formed on the wiring board may be formed of Sn, Pb, Au, Ag, Cu, Ni, Fe, Pd, Bi, Zn, In, Sb, or Ge, or a mixture, compound or laminated film thereof.

FIG. 27 illustrates in detail a bump connecting structure of the semiconductor chip shown in FIGS. 6 and 7. The Cu pad 2 is formed on the low dielectric constant insulating film (low dielectric constant layer) 12 formed of an SiOC film. The passivation film 3 is formed of a multilayer of SiO₂/SiN layers 3a and 3b.

Next, other examples of attaching bump electrodes to the semiconductor chip 1 are explained with reference to FIGS. 15-17. In FIG. 15, formed is a Cu pad 2 protected by a passivation film (SiO₂/SiN) 3 formed on a low dielectric constant insulating film 12 on the semiconductor chip 1. A passivation film (SiO₂/SiN) 3′ is formed on the Cu pad, such that the Cu pad 2 is partially exposed through an opening of the passivation film 3′. An Al pad 2′ is formed on the exposed part of the Cu pad 2 and on and around the opening of the passivation film 3′, with a barrier metal layer (TaN) (not shown) interposed therebetween. TaN is mentioned as an example of the barrier metal layer which is formed on the CU pad to enhance adhesion between the Cu pad and the Al pad. The barrier metal layer may be Ta, Ti, TiN, or a laminated film or alloy film thereof. A passivation film (SiO₂/SiN) 3″ is formed thereon, such that the Al pad 2′ is partially exposed through an opening of the passivation film 3″. A solder bump 9 is connected to the exposed part of the Al pad 2′ and to the opening, and a surrounding portion thereof, of the passivation film 3″, with a barrier metal layer (Pd/Ni/Ti) interposed therebetween. As described above, a Cu pad and an Al pad can be used together. In this example, the low dielectric insulating film 12 is formed of two low dielectric constant layers formed of SiOC films, in which respective Cu wire portions 12a and 12b are formed. The Cu pad 2 is electrically connected to element portions 1a formed in the semiconductor chip (Si chip) 1 and including transistors and the like, via the Cu wire portions 12a and 12b.

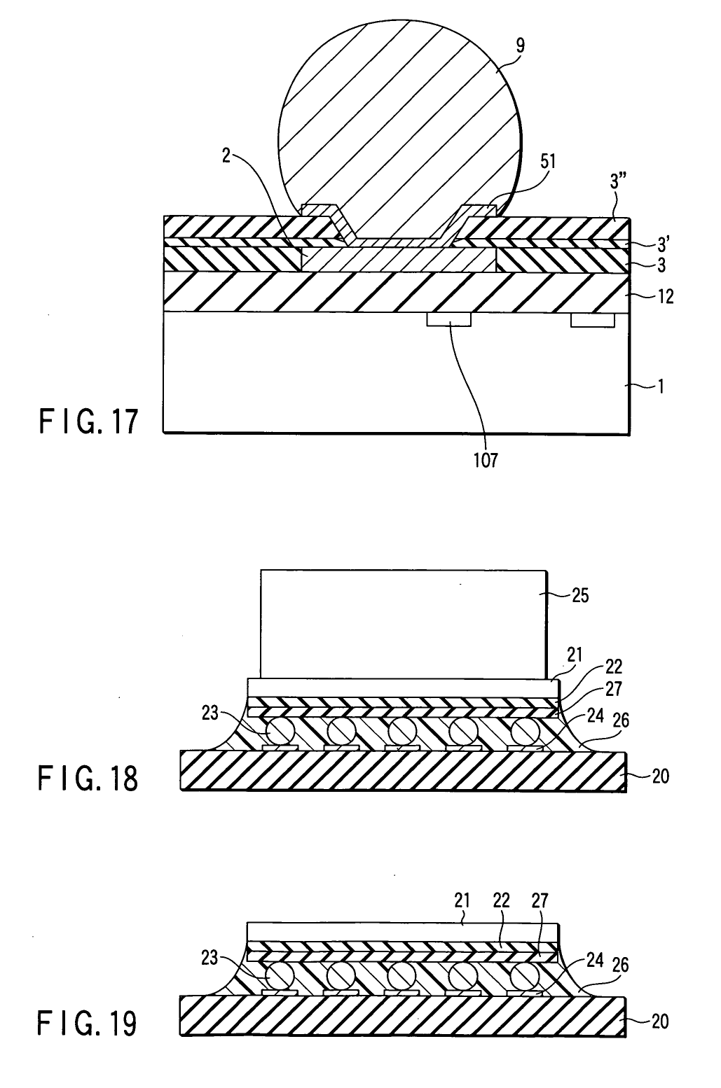

Next, FIGS. 16 and 17 illustrate examples in which a polyimide film is used in a passivation film. FIG. 16 illustrates a modification of the structure of FIG. 15, and FIG. 17 illustrates a modification of the structure of FIG. 27. In FIG. 16, formed is a Cu pad 2 protected by a passivation film (SiO₂/SiN) 3 formed on a low dielectric constant insulating film 12 on a semiconductor chip 1. A passivation film (SiO₂/SiN) 3′ is formed thereon, such that the Cu pad 2 is partially exposed through an opening of the passivation film 3′. An Al pad 2′ is formed on the exposed part of the Cu pad 2 and on and around the opening of the passivation film 3′, with a barrier metal layer (TaN) (not shown) interposed therebetween. A passivation film 3″ is formed thereon, such that the Al pad 2′ is partially exposed through an opening of the passivation film 3″. The passivation film 3″ is formed of an SiO₂/SiN film and a polyimide film layered thereon. A solder bump 9 is connected to the exposed part of the Al pad 2′ and to the opening, and a surrounding portion thereof, of the passivation film 3″, with a barrier metal layer (Pd/Ni/Ti) 51 interposed therebetween. As described above, the Cu pad 2 and the Al pad 2′ can be used together. In this example, the low dielectric insulating film 12 is formed of low dielectric constant layers formed of SiOC films in which Cu wire portions, not shown, are formed (FIG. 15). The Cu pad 2 is electrically connected to element portions 107 formed in the semiconductor chip (Si chip) 1 and including transistors and the like, via the Cu wire portions 12a and 12b.

In FIG. 17, formed is a Cu pad 2 protected by a passivation film (SiO₂/SiN) 3 formed on a low dielectric constant insulating film 12 on a semiconductor chip 1. A passivation film 3′ is formed thereon, such that the Cu pad 2 is partially exposed through an opening of the passivation film 3′. A solder bump 9 is connected to the exposed part of the Cu pad 2 and to and around the opening of the passivation film 3′, with a barrier metal layer (Pd/Ni/Ti) 51 interposed therebetween. The passivation film 3′ is formed of an SiO₂/SiN film and a polyimide film layered thereon.

As described above, in flip chip connecting of the semiconductor chip to the board, the resin changes from liquid to solid when the bump electrodes are in a molten state. Therefore, the bump electrodes are protected, and not strained by heat. That is, strain on the bump electrodes is relieved. Even if a low dielectric constant insulating film (Low K film) having a relative dielectric constant of 3.5 or less as in this embodiment is used in the semiconductor chip, the bump electrodes do not peel off, and the reliability of the semiconductor device is improved. The coefficient of elasticity of the resin in this state is about 20 MPa or more. In FIGS. 16 and 17, the Cu wirings are omitted for simplicity.

In the above embodiment, Ti, Ni and Pd are used as the barrier metal for bumps. However, the barrier metal may be a single layer of Ti, Cr, Cu, Ni, Au, Pd, TiW, W, Ta, TaN, TiN or Nb, or a laminated film or alloy film thereof. Even if the adhesion strength of the metal wire used as the wire, the metal pads and the barrier metal to the insulating film, metal film and the semiconductor chip is 15 J/m² or less, the films do not peel off. Further, not only the Low K film but also the metal film can be prevented from peeling off. Examples of the organic film formed on the semiconductor chip are a polyimide film and a BCB (Benzocyclobutene) film, etc.

Next, a second embodiment is explained with reference to FIGS. 18 and 19.

FIGS. 18 and 19 are cross-sectional views for explaining process of flip chip connecting of a semiconductor chip, with which bump electrodes are connected, to a wiring board. First, bump electrodes (solder bump (Sn—Pb solder)) 23 of a semiconductor chip 21 are formed in the same manner as in the first embodiment. A low dielectric constant insulating film 22 is formed on the semiconductor chip 21, and the surface of the semiconductor chip 21 is coated and protected with a passivation film 27. First, an oxide film formed on the surface of the solder is removed, and a proper amount of resin 26 having a flux function is applied onto connecting pads 24 of a wiring board 20. The bump electrodes 23 are aligned with the respective connecting pads 24 on the wiring board 20 such as a printed board, and they are provisionally fixed by applying pressure of 50 kg for 2 seconds. Thereafter, they are heated on the side of a tool 25 of a flip chip bonder, and thereby heated to 220° C. in about 3 to 10 seconds, and maintained at 220° C. for 1 to 20 seconds to bond the solder bumps 23 to the connecting pads 24 of the wiring board 20. Thereafter, the tool 25 is cooled. In this process, it was monitored that the resin 26 changed from liquid to solid when the connecting pads 24 are in a molten state. The coefficient of elasticity of the resin in this state is 20 MPa or more, preferably 100 MPa or more. Although this semiconductor chip sample was further cured at 150° C. for 2 hours, the Low K film did not peel off.

A semiconductor device was manufactured according to the above process, and reliability of the device was checked by a temperature cycle test. A 15 mm square chip in which 2500 bumps are formed was used as semiconductor chip, and a sample was made by mounting the chip on a resin board. The temperature cycle test was performed with a cycle comprising −55° C. (30 min), 25° C. (5 min) and 125° C. (30 min) performed in this order.

As a result, no break was found in the connecting portions after 1500 cycles. Further, no peeling of the Low K film 22 formed in the semiconductor chip was occurred. Furthermore, neither the Low K film 22 nor bumps peeled off after moisture absorption reflow evaluation.

Although this embodiment shows an example of using an SiOC film as Low K film, the Low K film may be formed of one of HSQ, Organic Silica, porous HSQ, and BCB, or a laminated film or porous film thereof. An SiO₂ film, an SiN film or a film obtained by superposing these films may be used as the Low K film.

The resin having the flux function may be a resin in which a flux is mixed, a resin including a curing agent having a flux effect, and a resin using an acid anhydride as such a curing agent. Further, a resin in which filler is mixed may be used.

Further, although Sn—Pb solder is used as the bump electrodes in this embodiment, the bump electrodes may be formed of Au, Ag, Cu, Ni, Fe, Pd, Sn, Pb, Bi, Zn, In, Sb, or Ge, or a mixture or compound thereof. The connecting pads of the wiring board may be formed of Sn, Pb, Au, Ag, Cu, Ni, Fe, Pd, Bi, Zn, In, Sb, or Ge, or a mixture, compound or laminated film thereof.

In this embodiment, the bump electrodes and the connecting pads are heated by using a flip chip bonder, instead of a reflow furnace. It produces substantially the same effect as that in the first embodiment.

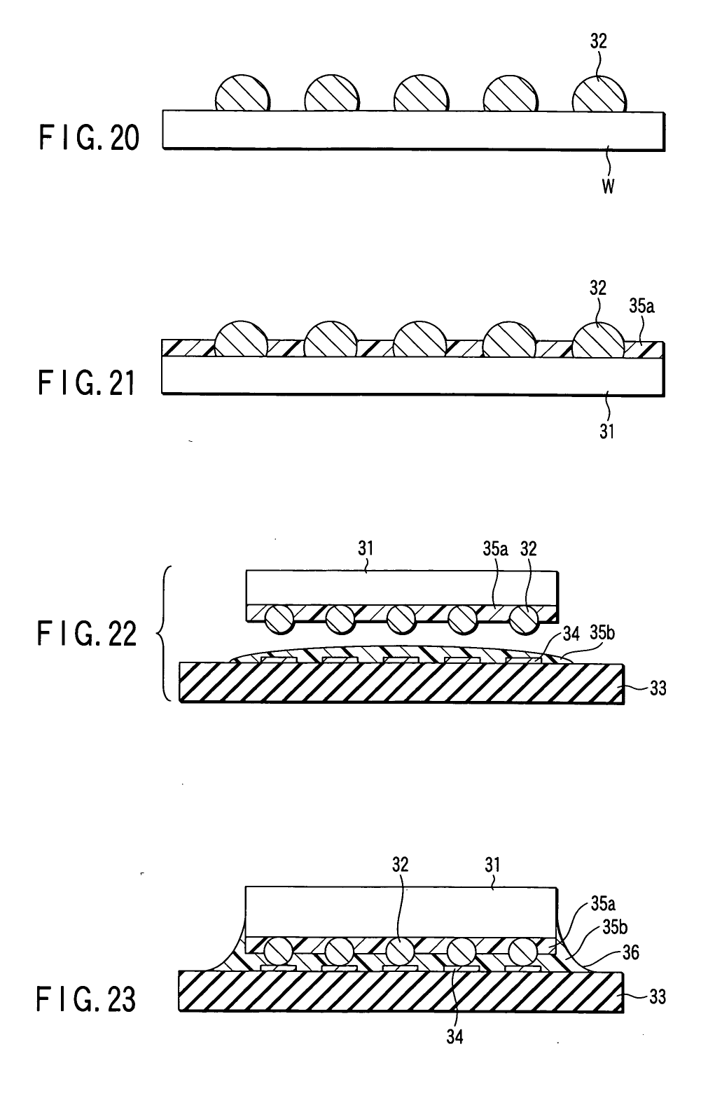

Next, a third embodiment is explained with reference to FIGS. 20-23.

FIGS. 20-23 are cross-sectional views illustrating a method of manufacturing a semiconductor device of the present invention. First, bump electrodes (solder bumps) 32 having a bump structure shown in FIG. 5 or 15 are formed on a semiconductor wafer W formed of silicon or the like (FIG. 20). Next, a resin 35a having a flux function with a coefficient of elasticity of 20 MPa or more at normal temperature is applied over the surface of the semiconductor wafer W. The thickness of the resin is about 50% to 90% of the height of the solder bumps 32. Then, the semiconductor wafer W is carried into a reflow furnace or the like, to melt the solder bumps 32 and allow the solder bumps 32 to be further exposed from an upper surface of the resin 35a (FIG. 21). In this process, the bumps can be exposed from the resin since the resin having a flux function is used. Since the melting of solder is promoted by the flux effect, it is possible to allow the bumps to be exposed from the resin 35a by surface tension. Since it is difficult to allow the bumps to be exposed from the resin in the case of using normal resin, it is important-to use a resin having such a flux function. Filler may be mixed into the resin having a flux function. Adding filler decreases the thermal expansion coefficient of the resin, and improves the reliability of the resin.

Next, the semiconductor wafer W with the resin 35a is subjected to dicing to cut the semiconductor wafer W into a plurality of semiconductor chips. Then, an oxide film formed on the surface of solder formed on a wiring board 33 is removed, and a proper amount of resin 35b having a flux function is applied onto connecting electrodes (connecting pads) 34 of the wiring board 33. A non-filler resin is used as the resin 35b. Using the resin containing no filler for connecting achieves good connecting of the connecting pads 34 of the wiring board 33 to the solder bumps 32 of the semiconductor chip 31 (FIG. 22).

Next, the connecting pads 34 of the wiring board 33 such as a printed board are aligned with the respective solder bumps 32, and the connecting pads 34 and the solder bumps 32 are provisionally fixed by pressing. Thereafter, they are carried into a reflow furnace, and the solder bumps 32 and the respective connecting pads 34 are connected therein (FIG. 23). Further, the connected material is dried in an oven to formally cure the resin.

A semiconductor device was manufactured according to the above process, and reliability of the device was checked by a temperature cycle test. A 15 mm square chip in which 2500 bump electrodes are formed was used as semiconductor chip, and a sample was made by mounting the chip on a resin wiring board. The temperature cycle test was performed with a cycle comprising −55° C. (30 min), 25° C. (5 min) and 125° C. (30 min) performed in this order.

As a result, no break was found in the connecting portions after 1500 cycles. Further, although the Sn—Pb solder is used as the bump electrodes in this embodiment, the bump electrodes may be formed of Au, Ag, Cu, Ni, Fe, Pd, Sn, Pb, Bi, Zn, In, Sb, or Ge, or a mixture or compound thereof. The connecting pads of the wiring board may be formed of Sn, Pb, Au, Ag, Cu, Ni, Fe, Pd, Bi, Zn, In, Sb, or Ge, or a mixture, compound or laminated film thereof.

As described above, in flip chip connecting of the semiconductor chip to the board, the resin changes from liquid to solid when the bump electrodes are in a molten state. Therefore, the bump electrodes are protected, and not strained by heat. Even if a low dielectric constant insulating film (Low K film) is used in the semiconductor chip, the bump electrodes do not peel off, and the reliability of the semiconductor device is improved. Further, using a non-filler resin as the resin having a flux function achieves good connection between the bump electrodes and the connecting pads.

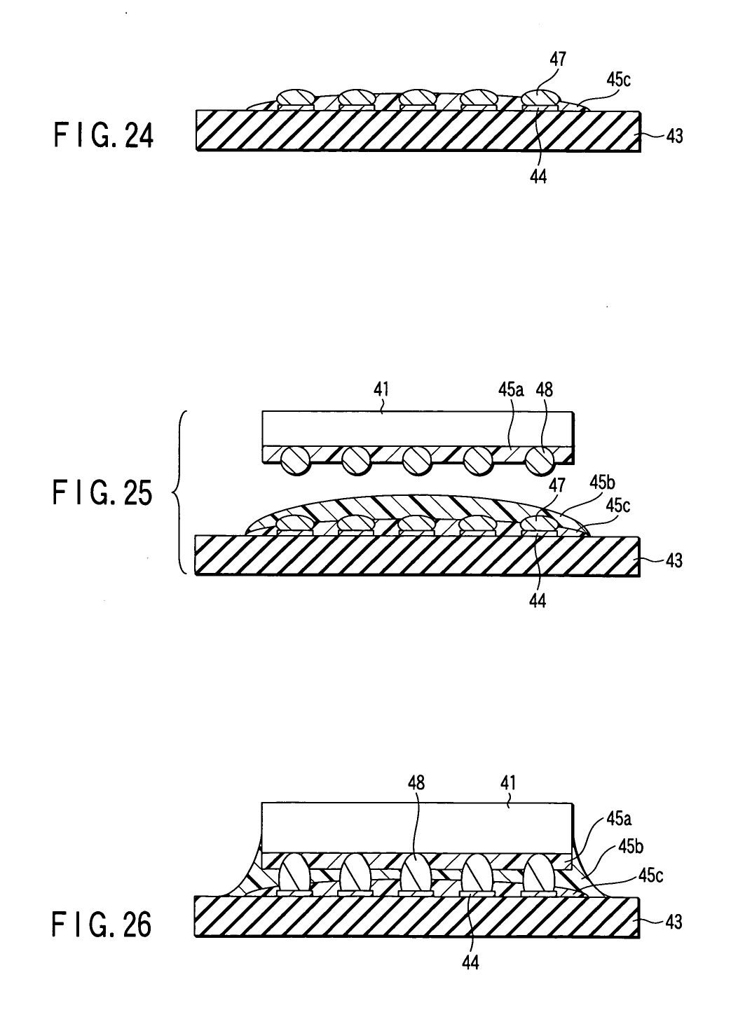

Next, a fourth embodiment is explained with reference to FIGS. 24-26.

FIGS. 24-26 are cross-sectional views illustrating a manufacturing method of a semiconductor device of the present invention. Bump electrodes (solder bumps), each of which having a bump structure shown in FIG. 5 or 15, are formed on a semiconductor wafer such as silicon. Connecting pads 44 are formed on wiring board 43, and bump electrodes 47 are formed thereon (refer to FIG. 24). In the same manner as in the third embodiment, a resin 45a having a flux function with a coefficient of elasticity of at least 20 MPa at normal temperature is applied to the semiconductor wafer 41. The resin 45a has a thickness of 50% to 90% of the height of the solder bumps 48 formed on the semiconductor wafer 41.

Next, the semiconductor wafer is carried into a reflow furnace or the like to melt the solder bumps, and the solder bumps are exposed from the resin.

In this embodiment, a fast-cure resin 45c having a flux function is also applied to a wiring board 43. The resin 45c having a thickness of 50% to 90% of the height of the solder bumps 47 formed on the connecting pads 44 of the wiring board 43. Next, the wiring board 43 on which the resin 45c is formed is carried into a reflow furnace, to provisionally set the resin 45c. Since the resin has a flux function, the solder bumps 47 are exposed from an upper surface of the resin 45c.

A filler may be contained in the resin formed on the semiconductor wafer and in the resin formed on the wiring board side. Since a fast-cure resin is formed on the wiring board first, moisture is not easily removed from the board in comparison with the case of using an organic board, and no voids are generated.

Next, the semiconductor wafer on which the resin is formed is diced to form a plurality of semiconductor chips 41. Solder bumps 48 are formed on the semiconductor chip 41, and a resin 45a having a flux function is formed thereon. Then, an oxide film of the solder on the wiring board 43 is removed, and a proper amount of resin 45b having a flux function is applied onto the connecting pads 44 and the bump electrodes 47 of the wiring board 43 (FIG. 25). A non-filler resin is used as the resin 45b. Using a resin containing no filler for connecting of the solder bumps 47 and 48 of the wiring board and the semiconductor chip achieves good connection.

Next, the solder bumps on the respective connecting pads of the wiring board, such as a printed board, are aligned with the solder bumps of the semiconductor chip, and they are provisionally fixed by pressing (FIG. 25). Thereafter, they are carried into a reflow furnace, to bond the solder bumps to one another. Further, the connected board and the chip are dried in an oven to formally set the resins 45a, 45b and 45c, and thereby a resin molding 46 is formed (FIG. 26).

A semiconductor device was manufactured according to the above process, and reliability of the device was checked by a temperature cycle test. A 15 mm square chip in which 2500 bumps are formed was used as semiconductor chip, and a sample was made by mounting the chip on a resin board serving as wiring board. The temperature cycle test was performed with a cycle comprising −55° C. (30 min), 25° C. (5 min) and 125° C. (30 min) performed in this order.

As a result, no break was found in the connecting portions after 1500 cycles. Although the Sn—Pb solder bumps are used in this embodiment, the materials mentioned in the third embodiment may be used. Further, the connecting pads of the wiring board may be formed of the materials mentioned in the third embodiment.

As described above, in this embodiment, in flip chip connecting, the resin changes from liquid to solid when the bump electrodes are in a molten state. Therefore, the bump electrodes are protected, and not strained by heat. Even if a low dielectric constant insulating film (Low K film) is used in the semiconductor chip, the bump electrodes do not peel off, and the reliability of the semiconductor device is improved. Further, since a non-filler resin is used as the resin having a flux function, good connection of the bump electrodes to the connecting pads is achieved.

In each of the embodiments, a Cu pad, a barrier metal film, etc. are provided between the surface of the semiconductor chip and the bump electrodes.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor chip having a semiconductor element or an integrated circuit formed in the semiconductor chip, a low dielectric constant insulating film formed on a surface of the semiconductor chip, and a plurality of bump electrodes being provided on the surface of the semiconductor chip;
a wiring board having a plurality of connecting electrodes being electrically connected to the bump electrodes; and
a resin molding filled in a space between the semiconductor chip and the wiring board, the electrically connected bump electrodes and the connecting electrodes being arranged in the space,
wherein the resin molding is formed of a resin having a flux function and changed from liquid to solid when the bump electrodes are in a molten state.

2. A semiconductor device according to claim 1, wherein a relative dielectric constant of the low dielectric constant insulating film is about 3.5 or less.

3. A semiconductor device according to claim 1, wherein an adhesion strength of the low dielectric constant insulating film to each of the semiconductor chip, the insulating film, and a metal film is 15 J/m² or less.

4. A semiconductor device according to claim 2, wherein an adhesion strength of the low dielectric constant insulating film to each of the semiconductor chip, the insulating film, and a metal film is 15 J/m² or less.

5. A semiconductor device according to claim 1, wherein a coefficient of elasticity of the resin is 20 MPa or more at normal temperature.

6. A semiconductor device according to claim 1, wherein the resin molding comprises a first resin layer close to the semiconductor chip and a second resin layer close to the wiring board, and the second resin layer is a resin layer which does not contain a filler.

7. A semiconductor device according to claim 1, wherein the resin molding comprises a first resin layer close to the semiconductor chip, a second resin layer close to the wiring board, and a third resin layer interposed between the first resin layer and the second resin layer, and the third resin layer is a resin layer which does not contain a filler.

8. A semiconductor device according to claim 1, wherein the bump electrodes of the semiconductor chip are electrically connected to a plurality of connecting electrodes formed on the semiconductor chip, a part of the connecting electrodes are coated with a passivation film comprising at least one layer formed of an organic film.

9. A method of manufacturing a semiconductor device, comprising:
forming a plurality of bump electrodes on a surface of a semiconductor chip, in which a semiconductor element or an integrated circuit is formed, with a low dielectric constant insulating film formed on the surface of the semiconductor chip;
interposing a resin, which has a flux function between the semiconductor chip and a wiring board in which a plurality of connecting electrodes are formed;
aligning the bump electrodes and the respective connecting electrodes with the resin interposed therebetween, and pressing the semiconductor chip and the connecting electrodes against each other; and
heating the semiconductor chip and the wiring board to electrically connect the bump electrodes to the respective connecting electrodes, and to form a resin molding formed of the resin to fill a space between the semiconductor chip and the wiring board,
wherein the resin is a resin which changes from liquid to solid when the bump electrodes are in a molten state in connecting of the bump electrodes to the respective connecting electrodes.

10. A method of manufacturing a semiconductor device according to claim 9, wherein a relative dielectric constant of the low dielectric constant insulating film is about 3.5 or less.

11. A method of manufacturing a semiconductor device, according to claim 9, wherein a coefficient of elasticity of the resin is 20 MPa or more at normal temperature.

12. A method of manufacturing a semiconductor device, according to claim 9, wherein the heating the semiconductor chip and the wiring board is performed in a reflow furnace, and reflow conditions are a temperature of at least 200° C. and a time of at least 60 seconds.

13. A method of manufacturing a semiconductor device, comprising:
forming a plurality of bump electrodes on a surface of a semiconductor chip, in which a semiconductor element or an integrated circuit is formed, with a low dielectric constant insulating film formed on the surface of the semiconductor chip;
interposing a first resin, which has a flux function, in the vicinity of the semiconductor chip, between the semiconductor chip and a wiring board in which a plurality of connecting electrodes are formed;
interposing a second resin, which has a flux functions and contains no filler, in the vicinity of the wiring board, between the semiconductor chip and the wiring board in which the plurality of connecting electrodes are formed;
aligning the bump electrodes and the respective connecting electrodes with the first and second resins interposed therebetween, and pressing the semiconductor chip and the connecting electrodes against each other; and
heating the semiconductor chip and the wiring board to electrically connect the bump electrodes to the respective connecting electrodes, and to form a resin molding formed of the first and second resins to fill a space between the semiconductor chip and the wiring board,
wherein the first and second resins are resins which change from liquid to solid when the bump electrodes are in a molten state in connecting of the bump electrodes to the respective connecting electrodes.

14. A method of manufacturing a semiconductor device according to claim 13, wherein a relative dielectric constant of the low dielectric constant insulating film is about 3.5 or less.

15. A method of manufacturing a semiconductor device, according to claim 13, wherein a coefficient of elasticity of the resin is 20 MPa or more at normal temperature.

16. A method of manufacturing a semiconductor device, according to claim 13, wherein the heating the semiconductor chip and the wiring board is performed in a reflow furnace, and reflow conditions are a temperature of at least 200° C. and a time of at least 60 seconds.

17. A method of manufacturing a semiconductor device, comprising:
forming a plurality of bump electrodes on a surface of a semiconductor chip, in which a semiconductor element or an integrated circuit is formed, with a low dielectric constant insulating film formed on the surface of the semiconductor chip;
interposing a first resin, which has a flux function, in the vicinity of the semiconductor chip, between the semiconductor chip and a wiring board in which a plurality of connecting electrodes are formed;
interposing a second resin, which has a flux functions, in the vicinity of the wiring board, between the semiconductor chip and the wiring board in which the plurality of connecting electrodes are formed;
interposing a third resin, which has a flux function and contains no filler, between the first resin and the second resin;
aligning the bump electrodes and the respective connecting electrodes with the first, second and third resins interposed therebetween, and pressing the semiconductor chip and the connecting electrodes against each other; and
heating the semiconductor chip and the wiring board to electrically connect the bump electrodes to the respective connecting electrodes, and to form a resin molding formed of the first, second and third resins to fill a space between the semiconductor chip and the wiring board,
wherein the first, second and third resins are resins which change from liquid to solid when the bump electrodes are in a molten state in connecting of the bump electrodes to the respective connecting electrodes.

18. A method of manufacturing a semiconductor device according to claim 17, wherein a relative dielectric constant of the low dielectric constant insulating film is about 3.5 or less.

19. A method of manufacturing a semiconductor device, according to claim 17, wherein a coefficient of elasticity of the resin is 20 MPa or more at normal temperature.

20. A method of manufacturing a semiconductor device, according to claim 17, wherein the heating the semiconductor chip and the wiring board is performed in a reflow furnace, and reflow conditions are a temperature of at least 200° C. and a time of at least 60 seconds.
